(19) United States
(12) Patent Application Publication
(10) Pub. No.: US 2014/0020734 A1
(43) Pub. Date: Jan. 23, 2014

(54) METHOD AND APPARATUS PROVIDING AN EXTRUDED EDGE SEAL ON A PHOTOVOLTAIC MODULE

(71) Applicant: FIRST SOLAR, INC, Perrysburg, OH (US)

(72) Inventors: Christopher Baker, Maumee, OH (US); Casimir Kotarba, Perrysburg, OH (US); Karina Krawczyk, Durham, NC (US); Paul Nawrocki, Rossford, OH (US); Nicholas St. John, Toledo, OH (US)

(21) Appl. No.: 13/943,854

(22) Filed: Jul. 17, 2013

Related U.S. Application Data
(60) Provisional application No. 61/672,545, filed on Jul. 17, 2012.
(60) Provisional application No. 61/678,848, filed on Aug. 2, 2012.

(51) Int. Cl. H01L 31/048; H01L 31/18; H01L 31/0203

(52) U.S. Cl. CPC H01L 31/0481; H01L 31/0203; H01L 31/18
USPC 136/251; 136/259; 136/252; 136/244; 438/64; 438/5

(57) ABSTRACT

An edge seal extruded onto at least a portion of one or more edges of a photovoltaic module is disclosed. A method for making a photovoltaic module comprising an extruded edge seal is also disclosed.

### CLAIM FOR PRIORITY

This application claims priority under 35 U.S.C. §119(e) to U.S. Provisional Patent Application Ser. Nos. 61/672,545 filed Jul. 17, 2012 and 61/678,848, filed Aug. 2, 2012, which are each hereby incorporated by reference in their entirety.

### FIELD OF THE INVENTION

The disclosed embodiments relate generally to a photovoltaic module, which may include modules containing one or more photovoltaic cells or any device that converts light to electricity, and more particularly, to a photovoltaic module with an extruded edge seal, and method for manufacturing the same.

### BACKGROUND

A photovoltaic module may include various internal components for producing electricity from light. For example, a photovoltaic module can include a front cover and a back cover. The front and back covers may be made of many different types of material, but are typically glass. A plurality of material layers, such as semiconductor materials and conductor materials, can be disposed between the front cover and the back cover. The semiconductor layers are often provided between conductor layers and generally include n-type and p-type semiconductor materials. The n-type and p-type semiconductor materials are disposed in close proximity to each other to form a p-n junction where light is converted to electricity. Using the conductor layers, the electricity may be provided to external devices. Hence, the semiconductor and conductor layers may collectively be referred to as an “active layer” of the photovoltaic module. The back cover together with the front cover form the outer surfaces of the module.

The internal structure of the modules, including the active layer, needs to be kept sealed from the surrounding external environment to prevent degradation of the layers. Further, they also need to be insulated to minimize any risk of electric shock from electricity generated by the module to those installing or servicing the module. As mentioned above, the back cover and front cover are often made of glass. As such, they serve in large measure to seal and insulate the module's interior from the external environment. However, the module edges are not covered by the front and back cover and thus are exposed to the external environment.

Presently, to seal and insulate the edges of a module, a portion of the active layer near the edge is removed through a process called “edge delete” to space the active layer away from the module's edges. After doing so, an insulating material is placed in the space that has been deleted to fill in the area. Depending on the insulating material, it may also be used to seal the edges of the module from the external environment. However, this process yields a photovoltaic module with less than optimal efficiency because the active area that has been deleted is not present to convert light to electricity. Also, additional manufacturing steps are required to make photovoltaic modules with edges that are insulated and sealed in this manner.

Consequently, an easier and more robust method and apparatus for providing an edge seal that may also be used to insulate the edge of a photovoltaic module is desired.

### DESCRIPTION OF THE DRAWINGS

FIG. 1A is a diagram of an extruding device adjacent to a photovoltaic module;

FIG. 1B is a diagram of an extruding device adjacent to a photovoltaic module;

FIG. 1C is a another diagram of an extruding device adjacent to a photovoltaic module;

FIG. 1D is a still another diagram of an extruding device adjacent to a photovoltaic module;

FIG. 1E is a diagram of an exemplary extruder head;

FIG. 1F is a diagram of another exemplary extruder head;

FIG. 2 is a diagram of a photovoltaic module with and extruding device in use;

FIG. 3 is a diagram of a photovoltaic module with an extruded edge seal;

FIG. 4A is a diagram of a photovoltaic module with an extruded edge seal;

FIG. 4B is a diagram of a photovoltaic module with an extruded edge seal; and

FIG. 5 is a flowchart showing a method of forming an extruded edge seal on a photovoltaic module.

### DETAILED DESCRIPTION

An edge seal can be extruded onto at least a portion of an edge of a photovoltaic module to seal and insulate the edge of the module. Extruding involves forming or shaping a material, often one or more polymers, by pushing it out through an orifice or die. An edge seal that is formed by extruding is known as an extruded edge seal, and has different physical properties from edge seals that are formed by other methods, such as spraying.

An extruded edge seal may include one or more polymeric materials. Applying the one or more polymeric materials by extrusion forms an edge seal on the top, bottom, and side edge of the photovoltaic module simultaneously. In some embodiments, the extruded edge seal may further comprise a bonding layer to ensure good adhesion of the extruded edge seal to the photovoltaic module. The bonding layer has acceptable adhesion to the front and back covers, to the side edge of the module, and to an overlying second layer of extruded material. The extruded edge seal can decrease the edge delete area because the bulk of the extruded layer can allow the active layer to extend closer to the module edges. The extruded edge seal can be simple to apply in a manufacturing setting.

Reference is now made to the Figures, wherein like reference numbers are used throughout to refer to like elements.

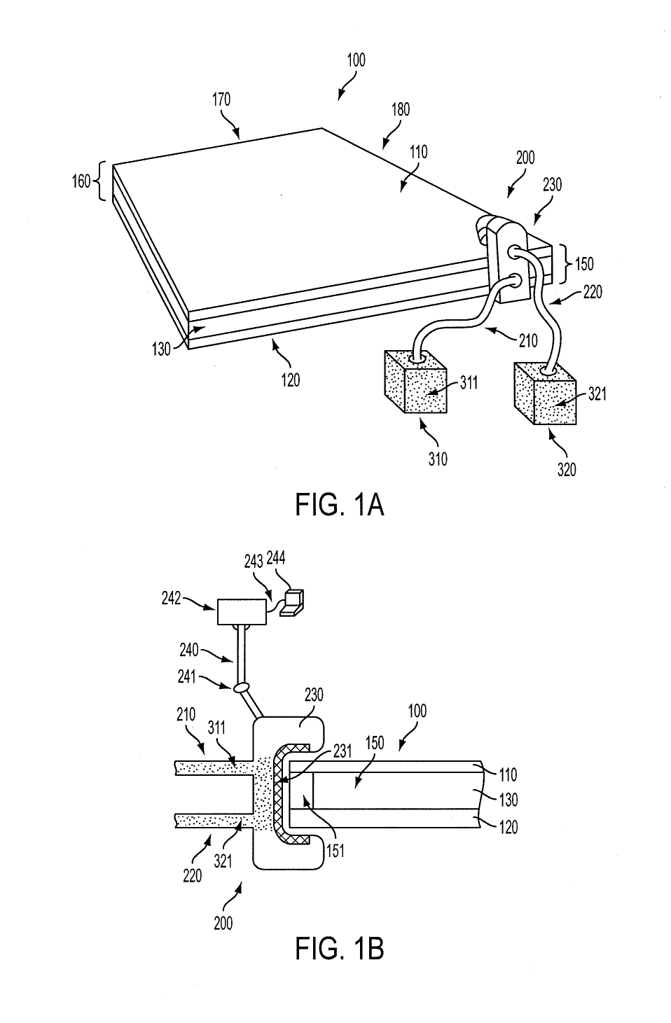

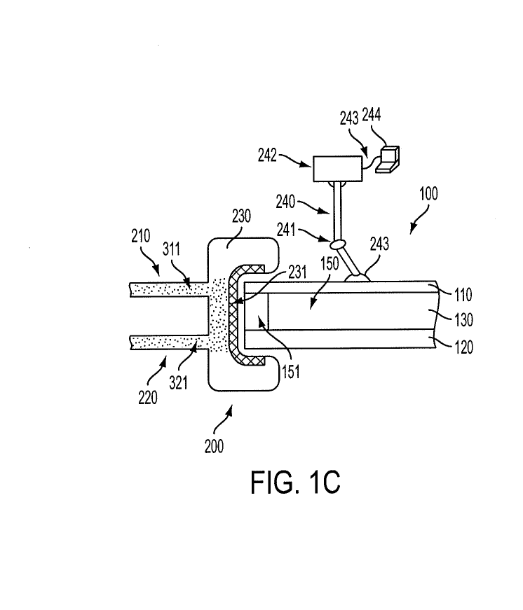

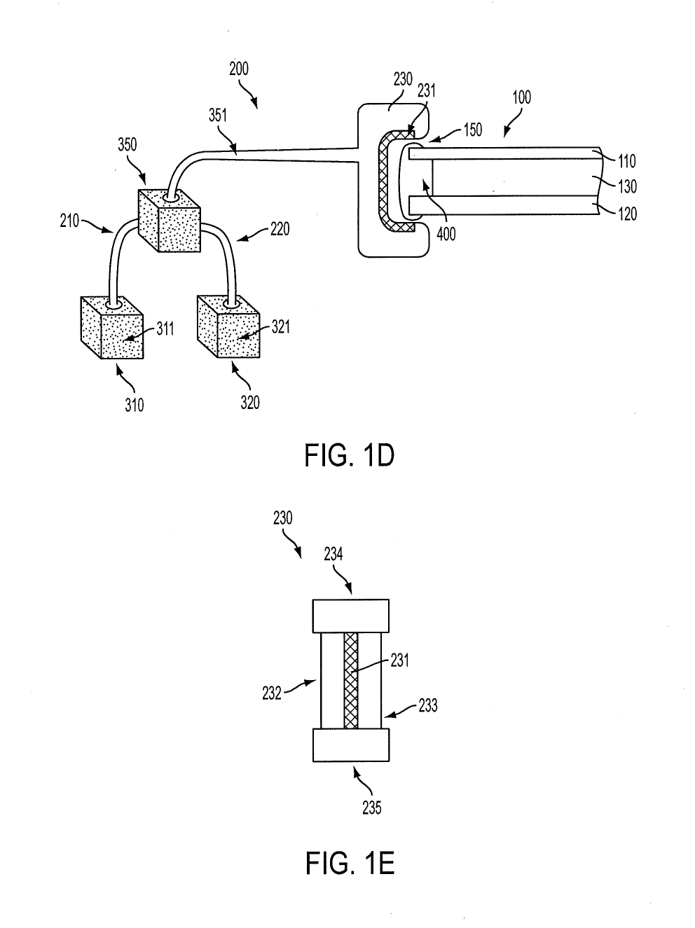

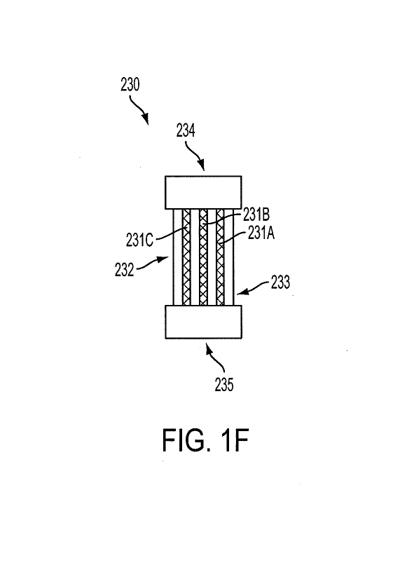

Referring first to FIG. 1A, a photovoltaic module 100 includes a front glass 110, an active layer 130 and a back glass 120. The photovoltaic module 100 features a first side edge 150, which extends along an edge of the module between two corners, a second side edge 160, a third side edge 170, and a fourth side edge 180. In this particular embodiment, the active layer 130 extends all the way to the side edges 150, 160, 170, and 180. As such, there is no edge delete area in FIG. 1A. The absence of an edge delete area means that more active layer is available for the conversion of light to electricity than in photovoltaic modules that have an edge delete area.

Adjacent to the photovoltaic module 100 is an extruding device 200. The extruding device 200 can be used to extrude polymers that may be used to seal and insulate the edges of the photovoltaic module 100. In this particular example, two polymers are used. To extrude the two polymers, a first material conduit 210 and a second material conduit 220 connected to extruder head 230 are used. The extruder head 230 is located adjacent to an edge, e.g., the first side edge 150, of the photovoltaic module 100. The first material conduit 210 is connected to a first container 310, and the second material conduit 220 is connected to a second container 320. The first container 310 holds a first polymer 311, which may be a liquid polymer (a liquid polymer is a polymer that is a liquid under extrusion conditions, such as a polymer that is melted under extrusion conditions), or a polymer solution (a polymer solution is a polymer that is dissolved in a solvent). The second container 320 holds a second polymer 321. Just as in the case of the first polymer, the second polymer may be a liquid polymer or a polymer solution. If the first polymer 311 and the second polymer 321 are extruded simultaneously, then they can be mixed inside the extruder head 230. Alternatively, as shown in FIG. 1D, a mixing chamber 350 may be provided between the containers 310 and 320, and the extruder head 230 to mix the first polymer with the second polymer. Otherwise a selection mechanism, such as one or more valves, can also be provided in the polymer flow path so that only one of the polymers is extruded at a time.

FIGS. 1B, 1C, and 1D are alternatives to the embodiment shown in FIG. 1A. FIG. 1B shows photovoltaic module 100 and extruding device 200. The extruder head 230 is generally C-shaped, so that an extrusion opening 231 of the extruder head 230 can be in a close proximity to the front glass 110, the back glass 120, and the active layer 130 near the first side edge 150 of the photovoltaic module 100. Unlike the embodiment shown in FIG. 1A, FIG. 1B depicts an active layer 130 that is recessed from the front glass 110 and back glass 120 at the first side edge 150, leaving a space between the front glass 110 and the back glass 120. This provides a distance known as “tracking distance,” from the active layer to the edge of the module. Tracking distances help prevent electrical leakage from the module, and are used to further separate the active layer 130 from the external environment. Filler 151, which may be a sealant material provided during manufacture of photovoltaic module 100, partially or completely fills the space between the front glass 110 and the back glass 120 along the perimeter of the photovoltaic module 100.

In use, the first polymer 311 and/or the second polymer 321 flow through opening 231 and are extruded onto the top of the front glass 110, the bottom of back glass 120, and the first side edge 150 simultaneously. The extruder head 230 is attached to an arm 240, which comprises a joint 241, and is attached to a moving module 242 which moves the arm 240 and the attached extruder head 230 to a desired position adjacent to an edge, such as the first side edge 150, of the photovoltaic module 100. The moving module 242 is in communication with a control unit 244 by way of a communication link 243, such as a wire or wireless link, that allows communication between the control unit 244 and the arm 240. The control unit 244 can be used to control the moving module 242 and the arm 240, including the joint 241, thereby moving extruder head 230 to a desired location or in a desired path. For example, the extruder head 230 can travel along at least a portion of an edge, such as the first side edge 150, of the photovoltaic module 100. In the same manner, the extruder head 230 can travel around the entire perimeter of the photovoltaic module 100. The control unit 244 is shown as being external to the extruding device 200, however, it may instead be integrated into the extruding device 200.

FIG. 1C is a cross-sectional profile view of a photovoltaic module 100 and extruding device 200. In FIG. 1C, the extruding device 200 has a fixed extruder head 230. The arm 240 and moving module 242 are connected to the photovoltaic device 100 by suction cup 243 to move the edges of the photovoltaic device 100 through the fixed extruder head 230 to extrude an edge seal by rotating the photovoltaic module 100 during extrusion. The edge seal can be extruded on one or more side edges of the photovoltaic module 100.

FIG. 1D is another cross sectional side profile view of photovoltaic module 100 and extruding device 200. The first polymer 311 and second polymer 321 are drawn out of the first container 310 and second container 320, respectively, and through the first material conduit 210 and second material conduit 220 into a mixing chamber 350. The first polymer 311 and second polymer 321 are mixed in the mixing chamber 330 and the mixture of the first polymer 311 and second polymer 321 is transported through a mixed-material conduit 351 to the extruder head 230.

FIG. 1E shows a front view of the extruder head 230, which includes a top 234, a bottom 235, a first side 232, and a second side 233. The extruder head 230 also includes an extrusion opening 231, which allows extruded materials to pass through the extruder head 230 and onto a side edge of a photovoltaic module 100. Extruder head 230 can be a fixed die or a variable die. If extruder head 230 is a fixed die, then the aperture of extrusion opening 231 does not vary. If extruder head 230 is a variable die, then the aperture of extrusion opening 231 can vary, for example to control the flow of extruded materials through the extrusion opening 231.

FIG. 1F shows a front view of a different configuration of the extruder head 230. Here, the extruder head 230 has multiple extrusion openings 231A, 231B, and 231C, each of which can be connected to a separate polymer container. As in FIG. 1E, extruder head 230 can be a fixed die or a variable die. If extruder head 230 is a fixed die, then the aperture of extrusion openings 231A-C do not vary. If extruder head 230 is a variable die, then the aperture of extrusion openings 231A-C can vary. This configuration may be useful, for example, in embodiments where the extruded edge seal contains more than one polymer layer. Exemplary embodiments with multiple polymer layers are discussed below.

Although FIGS. 1A-F show particular configurations of extruding device 200 and extruder head 230, extrusion may be accomplished by using any extruding device 200 known in the art. In some embodiments, such as when only a first polymer 311 is used, the extrusion device may only need first material conduit 210, and only one source of polymer material. In other embodiments, more than two material conduits and more than two containers, each holding one or more polymers, may be used.

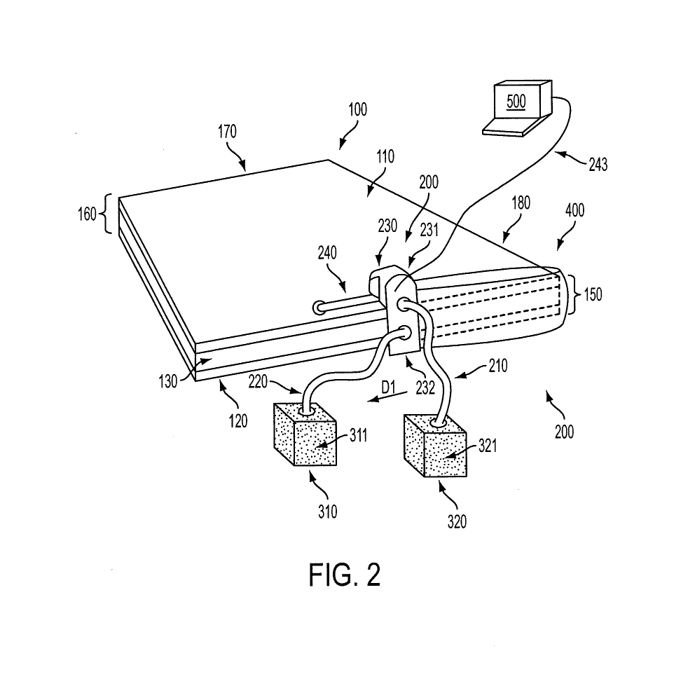

FIG. 2 shows the extruding device 200, which includes a sensing mechanism 240 that is operable during an extruding operation. The sensing mechanism 240 is configured to sense variations in the thickness and/or shape of photovoltaic module 100 at or near an edge, for example, the side edge 150. A communication link 243 reports these variations to a control module 500, which may, in response, alter one or more of the speed, direction, and path travelled by the extruder head 230, and/or the rate of polymer extrusion. For example, if a first polymer 311 and/or second polymer 321 is extruded, the control module can alter one or more of the speed, direction, path, and rate of extrusion of the first polymer 311 and/or second polymer 322, in order to ensure uniform and defect-free application of the first polymer 311 and/or second polymer 321. The rate of polymer extrusion can be altered, for example, by varying the flow rate of the first polymer 311 and/or the second polymer 321 through a first material conduit 210 or a second material conduit 220 with the control module 500. If the extruder head 230 is a variable die, then the rate of polymer extrusion can also be altered by varying the aperture of the extrusion opening 231 with the control module 500. A variable die can be particularly useful in applying a first polymer 311 and/or second polymer 321 to a photovoltaic module 100 with an inconsistent thickness. In FIG. 2, the control module 500 is shown as being external to the extruding device 200, however, it may instead be integrated into the extruding device 200, although this is not required. The control module 500 may also be integrated with the control unit 244 (FIG. 1), although this is also not required.

As extruder head 230 travels in direction D1 along the first side edge 150 of photovoltaic module 100, first polymer 311 and/or second polymer 321 is drawn out of first container 310 and/or second container 320 through first material conduit 210 and/or second material conduit 220. The first polymer 311 and/or the second polymer 321 are then extruded by the extruder head 230 directly onto the first side edge 150 of the photovoltaic module 100, thereby forming an extruded edge seal 400 over the first side edge 150.

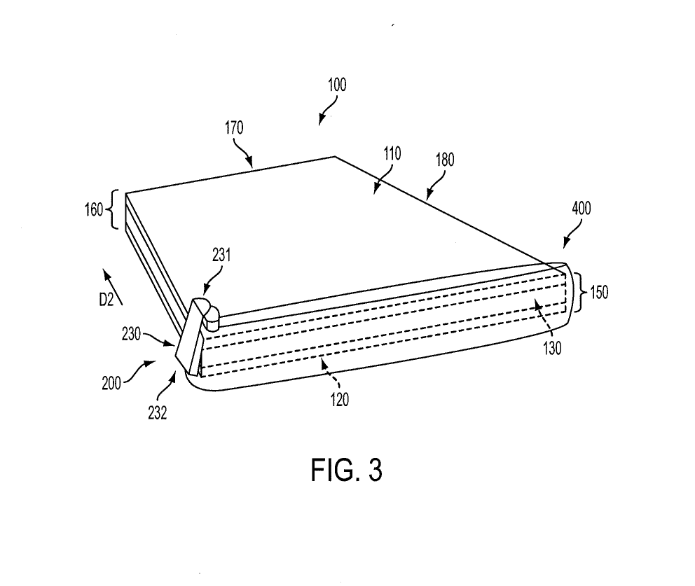

FIG. 3 shows the extruded edge seal 400 applied to the entire first side edge 150, including portions of the front glass 110 and the back glass 120 near first side edge 150. The extruder head 230 is now adjacent to the second side edge 160, and is travelling in direction D2 in order to apply the extruded edge seal 400 on the second side edge 160.

The one or more polymers used to form the extruded edge seal 400 can include any polymers known in the art that are suitable for extrusion. The polymers can be extruded as liquid polymers, or as polymer solutions that are suitable for extrusion. For example, the polymers can include, but are not limited to, silicone, poly(ethylene-co-methacrylic acid) such as Surlyn® (a registered trademark of E.I. du Pont de Nemours and Company), poly(ethylene vinylacetate) (EVA), ionomers, thermoplastic polyolefins (TPO), thermoplastic polyurethanes (TPU), poly(vinylbutylene) (PVB), poly(vinylydine chloride) (PVDF), poly(ethylene-co-tetrafluoroethalene) (ETFE), fluorinated ethylene propylene polymer (FEP), poly(ethylene chlorotetrafluoroethylene) (ECTFE), poly(ethylene terphthalate) (PET), poly(vinyl fluoride) (PVF), poly(vinyl chloride) (PVC), and poly(carbonate) (PC), copolymers thereof, and mixtures of any of the foregoing polymers and copolymers.

In some embodiments, the extruded edge seal 400 may contain only one first polymer 311. In other embodiments, the extruded edge seal 400 may contain a blend of more than one polymers.

In further embodiments, extruded edge seal 400 can include more than one polymer layer. In such embodiments, a first polymer can be extruded directly onto photovoltaic module 100, and a second polymer can then be extruded onto the first polymer to form a multi-layered extruded edge seal 400. The second polymer can be the same as or different from the first polymer. In still other embodiments, additional polymer layers can be extruded over the second polymer layer to form a multi-layered extruded edge seal 400.

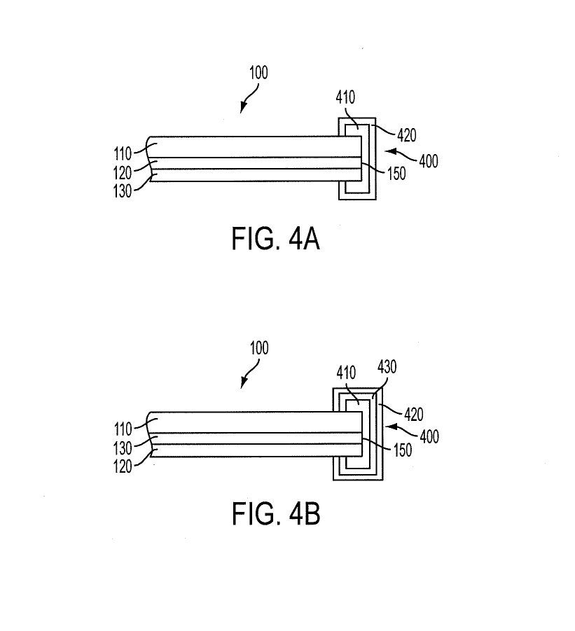

FIGS. 4A and 4B depict embodiments where edge seal 400 includes multiple polymer layers. In FIG. 4A, extruded edge seal 400 has been applied to first side edge 150. Extruded edge seal 400 includes first layer 410 and second layer 420. The first layer 410 may be, for example, a bonding layer that facilitates adhesion of a second layer 420 to the module 100, and may include, for example, silicone, poly(ethylene-co-methacrylic acid), EVA, copolymers thereof, or mixtures of any of the foregoing polymers and copolymers. The second layer 420 may be, for example, a dielectric layer for electrically insulating the active layer 130 from the module exterior, and may include, for example, PVDF, ETFE, FEP, ECTFE, PET, PVF, PC, copolymers thereof, or mixtures of any of the foregoing polymers and copolymers.

In FIG. 4B, edge seal 400 further includes a third layer 430, which is disposed between first layer 410 and second layer 420. Third layer 430 may be, for example, a thermoplastic encapsulant layer for encapsulating module edge, including the active layer 130, and may include, for example, TPE, TPO, PTU, PVB, copolymers thereof, or mixtures of any of the foregoing polymers and copolymers. In addition or alternative to being a thermoplastic the third layer 430 can be, for example, at least one of an adhesive layer for adhering the first and second layers and a layer that provides additional barrier properties, such as moisture barrier properties.

The extrusion head 230 can travel around the entire perimeter of the photovoltaic module 100 in a continuous manner. Thus, the extruded edge seal 400 can be applied to all four edges, 150, 160, 170, and 180 of the photovoltaic module 100 in a continuous process without interruption. Furthermore, because the extruder head 230 may have multiple material conduits each connected to containers holding different polymers, an extruded edge seal 400 having multiple layers can be formed in a continuous process. In such a process, each layer can be formed in a separate pass of the extruder head 230 around the perimeter of the photovoltaic module 100. For example, a three-layer extruded edge seal 400, such as the one depicted in FIG. 4B, can be formed using an extruder head 230 with three material conduits, each of the three material conduits connected to different containers holding, for example, three different polymers such as EVA, PVDF, and TPO. Particular configurations of extruder head 230, for example the configuration shown in FIG. 1E, may be useful in this embodiment. For example, if the extruder head 230 is used in the configuration shown in FIG. 1F, then EVA can be extruded through first opening 231A in the extruder head 230 during a first pass of the extruder head 230 around the photovoltaic module 100, PVDF can be extruded through second opening 231B during a second pass, and TPO can be extruded through third opening 231C during a third pass.

In other embodiments, the same result can be achieved with only a single material conduit. For example, a two-layer edge seal, such as the one depicted in FIG. 4A, can be formed using the extruder head 230 with only a first material conduit 210. The first material conduit 210 can be connected to a first container 310 containing, for example, EVA. The EVA can be extruded during a first pass of the extruder head 230 around the perimeter of the photovoltaic module 100. The first material conduit 210 can then be switched from the first container 310 to the second container 320, which can contain, for example, PVDF. The PVDF can be extruded during a second pass of the extruder head 230 around the perimeter of the photovoltaic module 100. A three-layer edge seal, such as the one depicted in FIG. 4B, can be formed by a similar method by switching from the second material container 320 to a third container that contains a third polymer. Switching can be accomplished by a switching mechanism including valves in one or more of the first material conduit 210, second material conduit 220, and extruder head 230.

In some embodiments, an edge seal 400 with more than one layer can be manufactured using more than one extruder head. For example, the first layer 410 can be formed on the photovoltaic module 100 using a first extruder head, which can extrude one or more components, such as one or more polymers, of the first layer 410 during a pass around a perimeter of the photovoltaic module 100. The third layer 430 can also be formed on top of the first layer 410 using a second extruder head, which can extrude one or more components, such as one or more polymers, of the third layer 430 during a pass around a perimeter of the photovoltaic module 100. The second layer 420 can be formed on top of the third layer 430 using a second extruder head, which can extrude one or more components, such as one or more polymers, of the second layer 420 during a pass around a perimeter of the photovoltaic module 100.

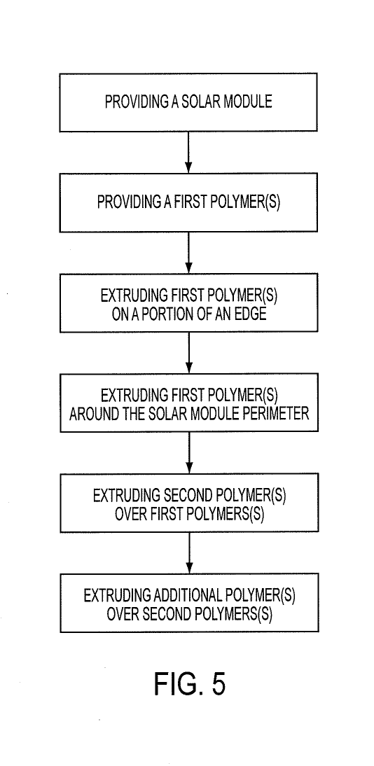

FIG. 5 is a flowchart delineating exemplary steps of a process that may be used to apply an extruded layer 400 around the edges of a photovoltaic module 100. The exemplary steps include providing the photovoltaic module 100 around the edges of which an insulated seal is to be provided. The insulated seal may include one or more polymers. An insulating seal that is suitable for extrusion can be provided. The insulating seal can be extruded. In the case, where the insulated seal is made up of one polymer, the polymer can be extruded around the edges of the module using one pass. In the case where the insulated seal is made up of more than one polymer, each polymer can be extruded around the edge of the module in each successive pass. Thus, there can be as many passes as there are polymers to be extruded.

Importantly, not all of the steps shown in FIG. 5 are required. For example, in some applications one or more side edges or one or more portions of side edges can be sealed by an extruded edge seal, and the remaining side edges or portions of side edges can be sealed by another means. In this case, steps involving extruding polymer(s) around the entire module perimeter can be omitted. If a single layer extruded edge seal 400 is required, then the steps of extruding a second polymer(s) over the first polymer(s) and extruding additional polymer(s) over the second polymer(s) can be omitted. If a two layer extruded edge seal 400 is required, then step of extruding additional polymer(s) over the second polymer(s) can be omitted.

A number of embodiments of the invention have been described. Nevertheless, it will be understood that various modifications may be made without departing from the spirit and scope of the invention. For example, while the invention has been described in relationship to a photovoltaic module having four edges, it can be applied to photovoltaic modules of any shape, including triangular, circular, hexagonal, etc. Furthermore, while the invention has been described in relationship to particular extruding devices, it should be understood that any device capable of applying an edge seal could be used. It should also be understood that the appended drawings are not necessarily to scale.

What is claimed as new and desired to be protected by Letters Patent of the United States is:

1. A photovoltaic module comprising:
a front cover; a back cover;
an active layer disposed between the front and back covers; and
an edge seal extruded onto both the front cover and the back cover for sealing the active layer.

2. The photovoltaic module of claim 1, wherein the edge seal further insulates the active layer.

3. The photovoltaic module of claim 1, wherein the at least one of the front cover and the back cover includes a glass.

4. The photovoltaic module of claim 1, wherein the edge seal comprises a first layer.

5. The photovoltaic module of claim 4, wherein the first layer comprises one or more polymeric materials selected from the group consisting of silicone, poly(ethylene-co-methacrylic acid), EVA, ionomers, TPO, TPU, PVB, PVDF, ETFE, FEP, ECTFE, PET, PVF, PC, copolymers thereof, and mixtures of any of the foregoing polymers and copolymers.

6. The photovoltaic module of claim 4, wherein the first layer is a bonding layer and the extruded edge seal further comprises at least a second layer over the bonding layer.

7. The photovoltaic module of claim 6, wherein the bonding layer selected from the group consisting of poly(ethylene-co-methacrylic acid), EVA, copolymers thereof, and mixtures of any of the foregoing polymers and copolymers

8. The photovoltaic module of claim 4, wherein the edge seal further comprises a second layer.

9. The photovoltaic module of claim 8, wherein the second layer is a dielectric layer.

10. The photovoltaic module of claim 9, wherein the dielectric layer comprises a polymer selected from the group consisting of EVDF, ETFE, FEP, ECTFE, PET, PVF, PC, copolymers thereof, or mixtures of any of the foregoing polymers and copolymers.

11. The photovoltaic module of claim 10, wherein the dielectric layer comprises ETFE.

12. The photovoltaic module of claim 8, wherein the edge seal further comprises a third layer.

13. The photovoltaic module of claim 12, wherein the third layer is a thermoplastic encapsulant for encapsulating the photovoltaic module.

14. The photovoltaic module of claim 13, wherein the thermoplastic encapsulant comprises TPE, TPO, PTU, PVB, copolymers thereof, or mixtures of any of the foregoing polymers and copolymers.

15. The photovoltaic module of claim 1, wherein the active layer is recessed with respect to one or more edges of the photovoltaic module.

16. The photovoltaic module of claim 15, wherein
the recessed active layer leaves a space between the one or more edges of the front and back covers; and
wherein the space is at least partially filled with a filler.

17. The photovoltaic module of claim 16, wherein the filler is a sealant.

18. The photovoltaic module of claim 16, wherein the filler is at least a part of the edge seal.

19. A method of making a photovoltaic module with an edge seal, comprising:
extruding one or more materials onto at least a portion of at least one edge of the photovoltaic module to form an edge seal.

20. The method of claim 19, wherein the one or more materials are one or more polymeric materials.

21. The method of claim 20, wherein the one or more polymers comprise a polymer selected from the group consisting of silicone, poly(ethylene-co-methacrylic acid), EVA, ionomers, TPO, TPU, PVB, PVDF, ETFE) fluorinated ethylene propylene polymer FEP, ECTFE, PET, PVF, PC, copolymers thereof, and mixtures of any of the foregoing polymers and copolymers.

22. The method of claim 19, wherein
at least a portion of the edge seal is extruded from an extruding device comprising an extruder head; and
wherein the step of extruding one or more polymeric materials comprises at least one of moving the extruder head around at least a portion of a perimeter of the photovoltaic module while extruding the edge seal, and moving at least a portion of a perimeter of the photovoltaic module through the extruder head while extruding the edge seal.

23. The method of claim 22, wherein the extruding device further comprises a sensing mechanism for sensing variations in at least one of thickness and shape of the photovoltaic module.

24. The method of claim 22, further comprising transmitting one or more signals indicating variations in at least one of thickness and shape of the photovoltaic module to a control module that controls at least one of the operation of the extruder head and the movement of the photovoltaic module through the extruder head.

25. The method of claim 24, wherein in response to the one or more signals transmitted by the sensing mechanism, said control module causes a change in at least one of a direction traveled by the extruder head and a direction travelled by the photovoltaic module.

26. The method of claim 24, wherein in response to the one or more signals transmitted by the sensing mechanism, the control module causes a change in at least one of a path traveled by the extruder head and a path traveled by the photovoltaic module.

27. The method of claim 24, wherein in response to the one or more signals transmitted by the sensing mechanism, the control module causes a change in a rate of extrusion of one or more polymers from the extrusion device.

28. The method of claim 22, wherein moving the extruder head a comprises moving the extruder head in a first pass around the perimeter of the photovoltaic module in a while extruding a first layer of the one or more polymeric materials.

29. The method of claim 28 wherein moving the extruder head further comprises moving the extruder around the perimeter of the photovoltaic module in a second pass while extruding a second layer of the one or more polymers.

30. The method of claim 29, wherein the step of moving the extruder further comprises moving the perimeter of the photovoltaic module in a third pass while extruding a third layer of one or more polymers.

31. The method of claim 28, wherein the first layer of one or more polymers is a bonding layer.

32. The method of claim 29, wherein the second layer of one or more polymers is a dielectric layer.

33. The method of claim 30, wherein the third layer of one or more polymers is a thermoplastic encapsulant layer.

34. The method of claim 31, wherein the bonding layer comprises a polymer selected from the group consisting of silicone, poly(ethylene-co-methacrylic acid), EVA, copolymers thereof, and mixtures of any of the foregoing polymers and copolymers.

35. The method of claim 32, wherein the thermoplastic encapsulant layer comprises a polymer selected from the group consisting of TPE, TPO, PTU, PVB, copolymers thereof, and mixtures of any of the foregoing polymers and copolymers.

36. The method of claim 33, wherein the dielectric layer comprises a polymer selected from the group consisting of EVDF, ETFE, FEP, ECTFE, PET, PVF, PC, copolymers thereof, and mixtures of any of the foregoing polymers and copolymers.

37. The method of claim 22, wherein the extruder head is C-shaped.

38. The method of claim 22, wherein the photovoltaic module further comprises:
a front cover;
a back cover;
an active layer disposed between the front and back covers; and
wherein the step of extruding one or more polymers comprises extruding one or more polymers such that the one or more polymers contact at least a portion of the front cover and at least a portion of the back cover.

39. The method of claim 38, wherein at least one of the front cover and the back cover comprises glass.

40. The method of claim 22, wherein the step of extruding one or more polymeric materials further comprises:
extruding a first layer of the edge seal with a first extruder head; and
extruding a second layer of the edge seal with a second extruder head on the first layer of the edge seal.

41. The method of claim 40, further comprising extruding a third layer of the edge seal with a third extruder head.

42. The method of claim 40, wherein the first layer of the edge seal is a bonding layer.

43. The method of claim 40, wherein the second layer of the edge seal is a dielectric layer.

44. The method of claim 41, wherein the third layer of one or more polymers is a thermoplastic encapsulant layer.

45. The method of claim 42, wherein the bonding layer comprises a polymer selected from the group consisting of silicone, poly(ethylene-co-methacrylic acid), EVA, copolymers thereof, and mixtures of any of the foregoing polymers and copolymers.

46. The method of claim 43, wherein the thermoplastic encapsulant layer comprises a polymer selected from the group consisting of TPE, TPO, PTU, PVB, and mixtures of any of the foregoing polymers and copolymers.

47. The method of claim 44, wherein the dielectric layer comprises a polymer selected from the group consisting of EVDF, ETFE, FEP, ECTFE, PET, PVF, PC, copolymers thereof, and mixtures of any of the foregoing polymers and copolymers.

48. The method of claim 22, wherein moving the photovoltaic module through the extruder head a comprises moving the perimeter of the photovoltaic module through the extruder head in a first pass through the extruder head while extruding a first layer of the one or more polymeric materials.

49. The method of claim 48 wherein moving the photovoltaic module through the extruder head a comprises moving the perimeter of the photovoltaic module through the extruder head in a second pass through the extruder head while extruding a first layer of the one or more polymeric materials.

50. The method of claim 49, wherein the step of moving the extruder further comprises moving the perimeter of the photovoltaic module through the extruder head in a third pass through the extruder head while extruding a third layer of the one or more polymeric materials.

51. The method of claim 48, wherein the first layer of one or more polymers is a bonding layer.

52. The method of claim 49, wherein the second layer of one or more polymers is a dielectric layer.

53. The method of claim 50, wherein the third layer of one or more polymers is a thermoplastic encapsulant layer.

54. The method of claim 51, wherein the bonding layer comprises a polymer selected from the group consisting of silicone, poly(ethylene-co-methacrylic acid), EVA, copolymers thereof, and mixtures of any of the foregoing polymers and copolymers.

55. The method of claim 52, wherein the thermoplastic encapsulant layer comprises a polymer selected from the group consisting of TPE, TPO, PTU, PVB, copolymers thereof, and mixtures of any of the foregoing polymers and copolymers.

56. The method of claim 53, wherein the dielectric layer comprises a polymer selected from the group consisting of EVDF, ETFE, FEP, ECTFE, PET, PVF, PC, copolymers thereof, and mixtures of any of the foregoing polymers and copolymers.
